(19) United States
(12) Patent Application Publication
(10) Pub. No.: US 2026/0026361 A1
(43) Pub. Date: Jan. 22, 2026

(54) MANUFACTURING METHOD FOR PACKAGING SUBSTRATE

(71) Applicant: Absolics Inc., Covington, GA (US)

(72) Inventor: Jong Hyun LEE, Covington, GA (US)

(73) Assignee: Absolics Inc., Covington, GA (US)

(21) Appl. No.: 19/264,898

(22) Filed: Jul. 10, 2025

Related U.S. Application Data
(60) Provisional application No. 63/672,235, filed on Jul. 16, 2024.

(51) Int. Cl. H01L 21/48

(52) U.S. Cl. CPC H01L 21/4846

(57) ABSTRACT

A method for manufacturing a packaging substrate includes a preparation step of preparing a base substrate comprising a core substrate and an insulating layer disposed on the core substrate, an etching step of selectively etching the insulating layer using an etching mask, and a manufacturing step of manufacturing the packaging substrate from the base substrate after the etching step. The etching mask is disposed on the insulating layer and includes a metal pattern film and a resist pattern film disposed on the metal pattern film.

### CROSS-REFERENCE TO RELATED APPLICATION

This application claims the priority benefit of U.S. provisional Application Ser. No. 63/672,235, filed on Jul. 16, 2024. The entirety of the above-mentioned patent application is hereby incorporated by reference herein and made a part of this specification.

### BACKGROUND

### Technical Field

The present disclosure relates to a method for manufacturing a packaging substrate.

### Description of Related Art

In the manufacture of electronic components, implementing a circuit on a semiconductor wafer is called the front-end process (FE: Front-End), and assembling the wafer into a state that can be used in an actual product is called the back-end process (BE: Back-End), and the packaging process is included in this back-end process.

Recently, the four core technologies in the semiconductor industry that have enabled the rapid development of electronic devices are semiconductor technology, semiconductor packaging technology, manufacturing process technology, and software technology. Although semiconductor technology is advancing in various forms such as sub-micron to nanometer linewidths, tens of millions of cells, high-speed operation, and high heat dissipation, the technology for perfectly packaging these semiconductors has not been sufficiently supported in comparison. Accordingly, the electrical performance of a semiconductor may be determined not by the performance of the semiconductor technology itself, but by the packaging technology and the resulting electrical connection.

Recently, research is being conducted on applying ceramic materials to high-end packaging substrates. A through-hole is formed in a ceramic material substrate, and a conductive material is applied in this through-hole, allowing the wiring length between the device and the motherboard to be shortened and excellent electrical characteristics to be obtained.

### SUMMARY

A method for manufacturing a packaging substrate according to one embodiment of the present disclosure includes: a preparation step of providing a base substrate including a core substrate and an insulating layer disposed on the core substrate; an etching step of selectively etching the insulating layer using an etching mask; and a manufacturing step of manufacturing a packaging substrate from the base substrate after the etching step.

The etching mask is disposed on the insulating layer.

The etching mask includes a metal pattern film and a resist pattern film disposed on the metal pattern film.

The metal pattern film may include a first metal pattern layer and a second metal pattern layer disposed on the first metal pattern layer.

The first metal pattern layer may include at least one selected from the group consisting of titanium, nickel, chromium, molybdenum, tungsten, aluminum, and combinations thereof.

The second metal pattern layer may include copper.

The first metal pattern layer may be disposed in contact with an upper surface of the insulating layer.

The metal pattern film may be disposed in contact with the upper surface of the insulating layer.

A thickness ratio of the resist pattern film to the metal pattern film may be 0.15 or less.

A thickness ratio of the second metal pattern layer to the first metal pattern layer may be 0.5 to 10.

A thickness of the metal pattern film may be 100 μm to 250 μm.

The etching step may include: a mask formation process of forming the etching mask on the insulating layer; and a plasma etching process of selectively plasma-etching the insulating layer using the etching mask.

The resist pattern film may be removed during the plasma etching process.

The method for manufacturing a packaging substrate may further include a cleaning process of ultrasonic cleaning of the base substrate after the plasma etching process.

A vibration frequency of the cleaning process may be 20 kHz to 200 kHz.

The insulating layer after the etching step may include through-holes having a diameter of 3 μm to 50 μm.

### BRIEF DESCRIPTION OF THE DRAWINGS

FIG. 1 is a conceptual diagram illustrating a base substrate in the preparation step of the present disclosure.

FIG. 2A, FIG. 2B, and FIG. 2C are conceptual diagrams respectively illustrating the etching step of the present disclosure.

FIG. 3 is a conceptual diagram illustrating the packaging substrate manufactured through the manufacturing step of the present disclosure.

### DESCRIPTION OF THE EMBODIMENTS

Hereinafter, the embodiments will be described in detail with reference to the accompanying drawings so that those skilled in the art to which the present invention pertains may readily carry out the present disclosure. However, the present disclosure may be implemented in various different forms and is not limited to the embodiments described herein. Throughout the specification, the same reference numerals are assigned to similar parts.

In the entire specification, the term “combinations thereof” included in Markush-type expressions means a mixture or combination of one or more selected from the group of components listed in the Markush-type expression, and means that at least one selected from the group is included.

In the entire specification, terms such as “first”, “second”, or “A”, “B” are used to distinguish between identical terms. Also, a singular expression shall include a plural expression unless the context clearly indicates otherwise.

In the present specification, the term “-based” may mean a compound corresponding to “-” or a derivative of “-” in a compound.

In the present specification, the expression that B is located on A means that B is either directly positioned in contact with A or positioned on A with another layer in between, and is not to be interpreted as being limited to a structure in which B is in contact with the surface of A.

In the present specification, the expression that B is connected to A means that A and B are directly connected or connected through another component in between, and unless otherwise specified, it is not to be interpreted as limited to direct connection between A and B.

In the present specification, a singular expression, unless specifically stated otherwise, shall be interpreted to include both singular and plural as appropriate in the context.

In the present specification, the shapes, relative sizes, angles, and the like of respective components in the drawings may be exaggerated or illustrated for the purpose of explanation and may not limit the rights to the drawings.

In the present specification, the expression that A and B are adjacent means that A and B are either in contact with each other or located near each other without being in contact. Unless otherwise specified, it shall not be interpreted as limited to a case where A and B are in contact.

In the present specification, the term “fine line” refers to a line having a width of 5 μm or less, unless otherwise stated, and illustratively refers to a line having a width of 1 to 4 μm or less.

After forming a resist film in which a pattern is developed on the insulating layer, the insulating layer may be selectively etched to develop a pattern in the insulating layer. During the process of continuously performing selective etching of the insulating layer, an ambient temperature may rise above a certain level, whereby the resist pattern film may thermally deteriorate and stick onto the insulating layer. A thermally deteriorated resist pattern film may cause damage to the insulating layer during the stripping process, and in a case where the thermal deterioration of the resist pattern film is severe, stripping itself may become impossible.

It may be considered to remove the resist pattern film by ashing; however, this method may cause damage to the insulating pattern layer.

The inventors of the present disclosure have experimentally confirmed and completed the present disclosure that, by applying means such as an etching mask including a metal pattern film and a resist pattern film, the resist pattern film can be easily removed during the patterning process of the insulating layer, while more effectively suppressing damage to the insulating layer.

Hereinafter, the present disclosure will be described.

A method for manufacturing a packaging substrate according to the present disclosure includes a preparation step of providing a base substrate including a core substrate and an insulating layer disposed on the core substrate, an etching step of selectively etching the insulating layer using an etching mask, and a manufacturing step of manufacturing a packaging substrate from the base substrate after the etching step.

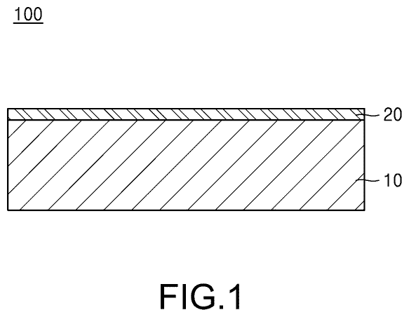

FIG. 1 is a conceptual diagram illustrating the preparation step of the present disclosure. With reference to FIG. 1, the method for manufacturing a packaging substrate according to the present disclosure will be described.

### Preparation Step

In the preparation step, a base substrate 100 including a core substrate 10 and an insulating layer 20 formed on the core substrate 10 may be provided.

The core substrate 10 may have the shape of a substrate. The core substrate 10 is not limited as long as it is a substrate applicable to electronic components.

A material for the core substrate 10 may include an organic material, glass, alumina, aluminum nitride, silicon carbide, or silicon nitride.

The core substrate 10 may be a glass core. The core substrate 10 may be, for example, an alkali borosilicate plate glass, an alkali-free borosilicate plate glass, or an alkali-free alkali-earth borosilicate plate glass. The core substrate 10 may be a glass substrate for an electronic device, and for example, it may be manufactured by companies such as Schott, AGC, or Corning, but is not limited thereto.

The core substrate 10 may include an upper surface and a side surface connected to the upper surface and formed in the thickness direction of the core substrate 10. The surface of the core substrate 10 may include a lower surface facing the upper surface.

That the side surface is formed in the thickness direction of the core substrate 10 is to be interpreted as including not only a case where the side surface forms a vertical angle with the upper surface of the core substrate 10, but also a case where at least a part of the side surface forms an angle (inclined angle) different from 90 degrees with the upper surface.

The side surface may be a flat surface or a curved surface.

The core substrate 10 may include a cavity (not shown), which is a space formed by a part of the core substrate 10 being recessed inward.

The cavity may be formed by a part of the upper surface and/or lower surface of the core substrate 10 being recessed in the thickness direction of the core substrate 10, or may be a through-structure penetrating the thickness of the core substrate 10.

The cavity may provide a space in which a device can be mounted. A device mounted in the cavity may be electrically connected with other components within the packaging substrate. The device may include not only a semiconductor device such as a CPU, GPU, or memory chip, but also a capacitor device, a transistor device, an impedance device, or other modules. That is, any device mountable on a semiconductor device may be applied without limitation as the above device.

The core substrate 10 may include a through-via portion (not shown) penetrating the thickness direction of the core substrate 10.

The through-via portion includes a via space in which a conductive layer (not shown) is disposed, and a via inner wall surface surrounding the via space. The via inner wall surface is a surface of the core substrate 10 formed inside the through-via portion.

The via space may have a substantially uniform inner diameter in the thickness direction of the core substrate 10. The via space may have a varying inner diameter in the thickness direction of the core substrate 10.

In the preparation step, when applying a glass core as the core substrate 10, the through-via portion may be formed by etching the glass core. Specifically, a defect may be formed at a predetermined position within the surface of the glass core. As a method of forming a defect, mechanical etching or laser irradiation may be applied.

The region where the defect is formed may be etched physically or chemically to form the through-via portion. When chemical etching is applied, wet etching using an etching solution may be carried out. The etching solution is not limited as long as it is commonly applicable to etching a glass substrate. For example, the etching solution may include sulfuric acid, nitric acid, hydrofluoric acid, etc.

In the etching process, the surface of the glass core excluding the region where the defect is formed may be masked, or etching may proceed without masking.

A defect may be formed at one point on the upper surface of the glass core, and another defect may be formed at a point on the lower surface of the glass core opposite the one point, and by etching, a core substrate 10 in which the through-via portion is formed may be prepared.

The base substrate 100 may include a conductive layer (not shown) formed in the via space. The conductive layer may be formed by being filled in at least a part of the via space or may be formed in a thin film form on the inner wall surface of the via. When the conductive layer is formed in a thin film form on the inner wall surface of the via, the remaining space in the via space other than the space occupied by the conductive layer may be filled with the insulating layer 20.

The conductive layer disposed in the via space may transmit an electrical signal in the thickness direction of the core substrate 10 and may electrically connect a device, a main board, a redistribution layer, and the like with each other.

The base substrate 100 may further include the insulating layer 20 formed on the core substrate 10. At least a part of the insulating layer 20 may be formed in contact with the upper surface of the core substrate 10. The base substrate 100 may further include the conductive layer (not shown). At least a part of the insulating layer 20 may be formed on the conductive layer. At least a part of the insulating layer 20 may be formed in contact with the upper surface of the conductive layer. The insulating layer 20 may be disposed in a mixed manner with the conductive layer. The insulating layer 20 may be disposed to surround the conductive layer.

The insulating layer 20 is not limited as long as it may be applied as an insulating layer to a semiconductor device or packaging substrate. For example, the insulating layer 20 may include an epoxy-based resin including a filler or the like. The insulating layer 20 may be formed using, for example, a build-up layer material such as Ajinomoto Build-up Film (ABF) from Ajinomoto Co., or an undercoat material, but is not limited thereto.

The conductive layer corresponds to a wire for transmitting an electrical signal. The conductive layer may include an electrically conductive material. For example, the conductive layer may include at least one of copper, nickel, aluminum, gold, or silver. Copper or the like may be applied as a material for the conductive layer.

In the preparation step, a base substrate 100 in which the insulating layer 20 is pre-formed on the core substrate 10 may be provided. In the preparation step, the insulating layer 20 may be formed on the core substrate 10 to provide the base substrate 100.

The insulating layer 20 may be formed by stacking an insulating resin in film form on the core substrate 10. For example, a film-type insulating layer 20 may be laminated under reduced pressure onto the core substrate 10 to form the base substrate 100. In this case, the surface of the conductive layer disposed under the insulating layer 20 may be surrounded without voids.

### Etching Step

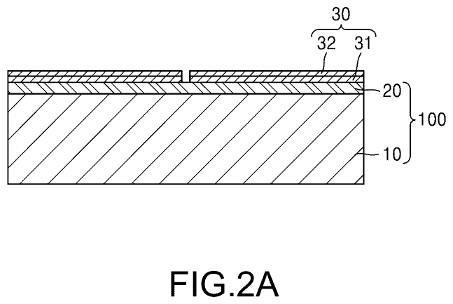

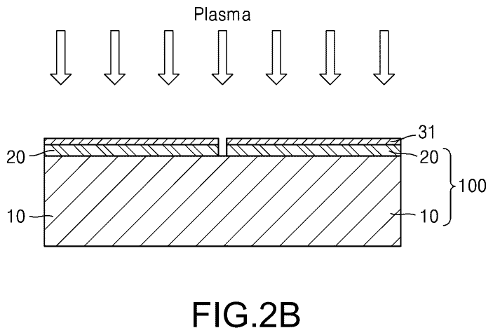

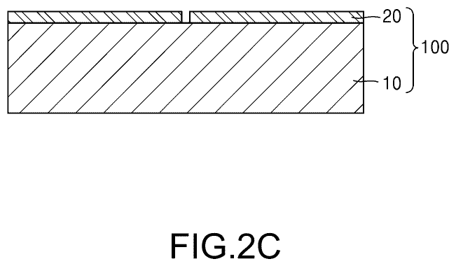

FIGS. 2A, 2B, and 2C are conceptual diagrams respectively illustrating the etching step of the present disclosure. With reference to FIGS. 2A, 2B, and 2C, the method for manufacturing a packaging substrate according to the present disclosure will be described.

An etching mask 30 may be disposed on the insulating layer 20. In the etching step, the insulating layer 20 may be selectively etched using the etching mask 30. In the etching step, the insulating layer 20 may be selectively plasma-etched using the etching mask 30.

### 1. Etching Mask Formation Process

The etching step may include an etching mask formation process of forming the etching mask 30 on the insulating layer 20.

The etching mask 30 may be applied to develop a predesigned pattern shape in the insulating layer 20 during the etching step. The etching mask 30 may include a pattern having the same shape as the pattern to be developed in the insulating layer 20 during the etching step. The etching mask 30 may include a hole pattern having the same shape as a hole pattern to be formed in the insulating layer 20 during the etching step.

The etching mask 30 of the present disclosure may include a metal pattern film 31 and a resist pattern film 32 disposed on the metal pattern film 31. The metal pattern film 31 may be disposed between the resist pattern film 32 and a non-etching region (not shown) within the insulating layer 20. In this case, even if the entire resist pattern film 32 is removed during the etching step, exposure of the upper surface of the insulating layer 20 may be prevented, and the metal pattern film 31 may protect the non-etching region within the insulating layer 20 from the etchant.

The non-etching region refers to a region in the insulating layer 20 that is not a target for etching, where the upper surface of the insulating layer 20 is not exposed due to the etching mask 30. The etching region refers to a region in the insulating layer 20 that is a target for etching, where the upper surface of the insulating layer 20 is exposed.

The metal pattern film 31 may be disposed in contact with the insulating layer 20. The metal pattern film 31 may have a two-layer structure. The present disclosure may dispose a metal pattern layer that exhibits relatively higher adhesion to the insulating layer 20 in contact with the upper surface of the insulating layer 20. This may help the etching mask 30 to be strongly bonded onto the insulating layer 20 and may more stably protect the non-etching region within the insulating layer 20.

The metal pattern film 31 may include a first metal pattern layer (not shown) and a second metal pattern layer (not shown) disposed on the first metal pattern layer.

The first metal pattern layer may be disposed in contact with the insulating layer 20. The second metal pattern layer may be disposed in contact with the upper surface of the first metal pattern layer. The second metal pattern layer may be fixed on the non-etching region in the insulating layer 20 through the first metal pattern layer.

The first metal pattern layer may include any one selected from the group consisting of titanium, nickel, chromium, molybdenum, tungsten, aluminum, and combinations thereof. The first metal pattern layer may include 50 atom % or more of any one selected from the group consisting of titanium, nickel, chromium, molybdenum, tungsten, aluminum, and combinations thereof. The first metal pattern layer may include 60 atom % or more of any one selected from the group consisting of titanium, nickel, chromium, molybdenum, tungsten, aluminum, and combinations thereof. The first metal pattern layer may include 70 atom % or more of any one selected from the group consisting of titanium, nickel, chromium, molybdenum, tungsten, aluminum, and combinations thereof. The first metal pattern layer may include 80 atom % or more of any one selected from the group consisting of titanium, nickel, chromium, molybdenum, tungsten, aluminum, and combinations thereof. The first metal pattern layer may include 90 atom % or more of any one selected from the group consisting of titanium, nickel, chromium, molybdenum, tungsten, aluminum, and combinations thereof. The first metal pattern layer may include 100 atom % or less of any one selected from the group consisting of titanium, nickel, chromium, molybdenum, tungsten, aluminum, and combinations thereof.

The first metal pattern layer may include titanium. The first metal pattern layer may include 50 atom % or more of titanium. The first metal pattern layer may include 60 atom % or more of titanium. The first metal pattern layer may include 70 atom % or more of titanium. The first metal pattern layer may include 80 atom % or more of titanium. The first metal pattern layer may include 90 atom % or more of titanium. The first metal pattern layer may include 100 atom % or less of titanium.

In such a case, during the etching step, the metal pattern film 31 may more stably adhere to the insulating layer 20.

A thickness of the first metal pattern layer may be 20 μm or more. The thickness of the first metal pattern layer may be 30 μm or more. The thickness of the first metal pattern layer may be 35 μm or more. The thickness of the first metal pattern layer may be 100 μm or less. The thickness of the first metal pattern layer may be 80 μm or less. The thickness of the first metal pattern layer may be 70 μm or less. The thickness of the first metal pattern layer may be 65 μm or less. In such a case, the first metal pattern layer may help the etching mask 30 to be uniformly adhered with a uniform force to the insulating layer 20 as a whole.

The second metal pattern layer may include copper. The second metal pattern layer may include 50 atom % or more of copper. The second metal pattern layer may include 60 atom % or more of copper. The second metal pattern layer may include 70 atom % or more of copper. The second metal pattern layer may include 100 atom % or less of copper. In such a case, even if the resist pattern film 32 is entirely removed during the etching step, the second metal pattern layer may stably protect the non-etching region within the insulating layer 20 from the etchant.

A thickness of the second metal pattern layer may be 50 μm or more. The thickness of the second metal pattern layer may be 60 μm or more. The thickness of the second metal pattern layer may be 70 μm or more. The thickness of the second metal pattern layer may be 80 μm or more. The thickness of the second metal pattern layer may be 200 μm or less. The thickness of the second metal pattern layer may be 180 μm or less. The thickness of the second metal pattern layer may be 160 μm or less. In such a case, it may be possible to maintain the metal pattern film 31 stably until completion of the plasma etching, and to remove the metal pattern film 31 relatively quickly through chemical etching.

A thickness of the metal pattern film 31 may be 100 μm or more. The thickness of the metal pattern film 31 may be 110 μm or more. The thickness of the metal pattern film 31 may be 120 μm or more. The thickness of the metal pattern film 31 may be 130 μm or more. The thickness of the metal pattern film 31 may be 250 μm or less. The thickness of the metal pattern film 31 may be 230 μm or less. The thickness of the metal pattern film 31 may be 220 μm or less. The thickness of the metal pattern film 31 may be 200 μm or less. In such a case, it may contribute to suppressing damage to the insulating layer 20 during the etching process on the insulating layer 20 and the process of removing the metal pattern film 31.

A thickness ratio of the second metal pattern layer to the first metal pattern layer may be from 0.5 to 10. The thickness ratio may be 0.7 or more. The thickness ratio may be 1 or more. The thickness ratio may be 1.3 or more. The thickness ratio may be 1.6 or more. The thickness ratio may be 8 or less. The thickness ratio may be 6 or less. The thickness ratio may be 4 or less. In such a case, it may provide the metal pattern film 31 with stable adhesion to the surface of the insulating layer 20, and may effectively protect the patterned insulating layer 20 from the etchant.

In the etching step, the resist pattern film 32 may be etched together during the process of patterning the insulating layer 20, and at the time when plasma etching is completed, the resist pattern film 32 may be substantially completely removed. Through this, it may be possible to suppress a portion of the resist pattern film 32 from remaining on the insulating layer 20, and to prevent defects from occurring in a redistribution layer including the insulating layer 20. In addition, since there is no need to introduce a separate process for removing the remaining resist pattern film 32, process efficiency may be improved.

The resist applicable to the resist pattern film 32 is not limited as long as it is commonly used in the field of packaging substrates. The resist may be an amine-based resist. The resist may be a positive resist. The resist may be a negative resist.

The resist pattern film 32 may be disposed on the metal pattern film 31. The resist pattern film 32 may be disposed in contact with the metal pattern film 31. The resist pattern film 32 may be disposed on the second metal pattern layer. The resist pattern film 32 may be disposed in contact with the second metal pattern layer.

A thickness ratio of the resist pattern film 32 to the metal pattern film 31 may be controlled within a predetermined range in the present disclosure. Through this, it may be possible to substantially remove the resist pattern film 32 at the time when the plasma etching process is completed, thereby improving process efficiency. Along with this, the resist pattern film 32 may have a thickness sufficient to protect the patterned insulating layer 20.

The thickness ratio of the resist pattern film 32 to the metal pattern film 31 may be 0.15 or less. The thickness ratio may be 0.13 or less. The thickness ratio may be 0.08 or more. In such a case, since there is no need to introduce a separate process for stripping or ashing the resist pattern film 32, process efficiency may be improved.

A thickness of the resist pattern film 32 may be 11 μm or more. The thickness may be 13 um or more. The thickness may be 15 μm or more. The thickness may be 24 μm or less. The thickness may be 22 μm or less. In such a case, the resist pattern film 32 may stably protect the insulating layer 20 being patterned from the etchant during the plasma etching process.

The etching mask 30 may be manufactured through the following process.

A metal film (not shown) may be formed on the insulating layer 20. Specifically, a first metal film (not shown) may be formed on the insulating layer 20 through sputtering, and a second metal film (not shown) may be formed on the first metal film through sputtering.

The metal film may be formed in contact with the upper surface of the insulating layer 20. The first metal film may be formed in contact with the upper surface of the insulating layer 20.

The first metal film may be formed of the same material as the first metal pattern film. The first metal film may be formed to have substantially the same thickness as the first metal pattern film.

The second metal film may be formed of the same material as the second metal pattern film. The second metal film may be formed to have substantially the same thickness as the second metal pattern film.

Descriptions of the composition and thickness of the first metal film and the second metal film are omitted as they are duplicates of the previous content.

A resist film (not shown) may be formed on the metal film. In order to improve adhesion of the resist film to the surface of the metal film, an adhesive may be applied over the entire metal film. The adhesive is not limited as long as it is commonly applicable in the field of resist films.

For example, hexamethyldisilazane may be applied as the adhesive.

The resist film may be formed by coating and curing a resist composition on the metal film. Description of the resist composition is omitted as it overlaps with previous content.

The resist composition may be coated so as to cover the entire insulating layer 20. A method for coating and curing the resist composition is not limited as long as it is commonly used in the field of packaging substrates. A thickness of the resist film formed by coating and curing the resist composition may be substantially the same as the thickness of the resist pattern film 32.

The resist film may be patterned to form the resist pattern film 32. Light may be selectively irradiated onto the resist film in correspondence with the pattern shape to be developed in the insulating layer 20. A light source applied for irradiating the resist film may be an electron beam. After the light irradiation, the irradiated resist film may be developed through a developer to form the resist pattern film 32.

After completing formation of the resist pattern film 32 on the metal film, the metal film may be patterned through the resist pattern film 32 to form the metal pattern film 31. The metal pattern film 31 may be formed through dry etching, or may be formed through wet etching. In order to prevent the resist pattern film 32 from being excessively thermally deteriorated during the patterning of the metal film, it is preferable to pattern the metal film through wet etching.

The etching mask 30 may include a through-hole pattern having a diameter of 3 μm to 50 μm. The diameter may be 5 μm or more. The diameter may be 7 μm or more. The diameter may be 40 μm or less. The diameter may be 30 μm or less. The diameter may be 20 μm or less. The diameter may be 15 μm or less. In such a case, it may be possible to finely form a high-integration fine wiring layer on the insulating layer 20.

### 2. Plasma Etching Process

The etching step may include an etching mask formation process and a plasma etching process of selectively plasma-etching the insulating layer 20 using the etching mask 30.

After placing the base substrate 100 on which the etching mask 30 is formed in an etching chamber, an etching gas may be introduced into the chamber, and plasma power may be applied to selectively etch a region of the insulating layer 20 where the upper surface is exposed, that is, an etching region.

During the plasma etching process, the resist pattern film 32 disposed on the insulating layer 20 may also be etched by the etchant. At the time when the plasma etching process is completed, the resist pattern film 32 may be substantially completely removed. In such a case, there is no need to introduce a separate process to remove the resist pattern film 32, and it is possible to reduce the possibility of the patterned insulating layer 20 being damaged during the process of removing the resist pattern film 32.

Even if the resist pattern film 32 is completely removed during the plasma etching process, the metal pattern film 31 may be maintained. The metal pattern film 31 may prevent the etchant from etching the non-etching region within the insulating layer 20 and may contribute to forming a fine redistribution layer.

The plasma etching process may be performed in an atmosphere containing an etching gas. The etching gas may include a first etching gas and a second etching gas.

The first etching gas is a fluorine-based gas. The first etching gas may be any one selected from the group consisting of fluorocarbon, fluoronitrogen, fluorosulfur, and combinations thereof. The fluorocarbon may be, for example, any one selected from the group consisting of CF₄, CHF₃, CH₂F₂, CH₃F, and combinations thereof. The fluoronitrogen may be NF₃. The fluorosulfur may be SF₆.

The first etching gas may include fluoronitrogen. The first etching gas may be fluoronitrogen.

The second etching gas may be oxygen gas.

In the present disclosure, the first etching gas and the second etching gas may be introduced together as atmosphere gas in the plasma etching process to further enhance the etching rate for the insulating layer 20 and the resist pattern film 32.

A plasma power applied in the plasma etching process may be 1.2 kW or more and 3 KW or less. The plasma power may be 1.5 kW or more. The plasma power may be 2.7 kW or less. The plasma power may be 2.5 kW or less. In such a case, it is possible to secure a sufficient etching rate for the insulating layer 20 and the resist pattern film 32, and to prevent the patterned insulating layer 20 from being excessively damaged due to plasma etching.

A maximum value of an ambient temperature in the etching step may be 120° C. or more. A maximum value of the ambient temperature in the plasma etching process may be 120° C. or more.

If the resist pattern film 32 is thermally deteriorated due to the ambient temperature in the chamber, it may be difficult to remove the resist pattern film 32 through a stripping process, and during the process of removing the pattern film, the patterned insulating layer 20 may be damaged.

To ensure convenience in the stripping process, when a separate cooling means or stabilization process is introduced to prevent the ambient temperature from rising above a certain level during the plasma etching process, production cost and time may increase.

In the present disclosure, since the resist pattern film 32 may be substantially removed by the etchant at the time the plasma etching process is completed, the present disclosure may reduce the time required for manufacturing the packaging substrate by continuously patterning the insulating layer 20 without considering thermal deterioration of the resist pattern film 32 due to ambient temperature.

The maximum value of the ambient temperature in the etching step may be 120° C. or more. The maximum value may be 140°° C. or more. The maximum value may be 200° C. or less.

The maximum value of the ambient temperature in the plasma etching process may be 120° C. or more. The maximum value may be 140° C. or more. The maximum value may be 200° C. or less.

In such a case, it may be possible to effectively reduce the time required to complete patterning of the insulating layer 20.

### 3. Cleaning Process

The etching step may further include a cleaning process of ultrasonically cleaning the base substrate 100 after the plasma etching process.

During the plasma etching of the insulating layer 20, particles originating from the insulating layer 20 or the resist pattern film 32 may be generated. The particles may remain and be adsorbed on the surface of the patterned insulating layer 20, and may become a factor that degrades electrical reliability of the manufactured packaging substrate.

In the cleaning process, the base substrate 100 may be immersed in a water tank, and ultrasonic vibration may be applied to the tank to cause cavitation. Through this, it may be possible to easily remove the particles adsorbed on the surface of the insulating layer 20 having a complex and fine structure without excessively damaging the base substrate 100.

A vibration frequency in the cleaning process may be 20 kHz to 200 kHz. The vibration frequency may be 30 kHz or more. The vibration frequency may be 50 kHz or more. The vibration frequency may be 70 kHz or more. The vibration frequency may be 150 kHz or less. In such a case, even if the insulating layer 20 has a fine and complex pattern structure, it may be possible to effectively remove the particles without causing significant deformation to the insulating layer 20.

### 4. Metal Pattern Film Removal Process

The etching step may include a metal pattern film (31) removal process for removing the metal pattern film (31) after the plasma etching process. To suppress damage and deformation of the patterned insulating layer (20), the metal pattern film (31) may be removed through wet etching. The wet etching of the metal pattern film (31) is not limited as long as it is conventionally applied in the etching field.

The insulating layer (20) after the etching step may include through-holes having a diameter of 3 μm to 50 μm. The diameter may be 5 μm or more. The diameter may be 7 μm or more. The diameter may be 40 μm or less. The diameter may be 30 μm or less. The diameter may be 20 μm or less. The diameter may be 15 μm or less. In such a case, it may contribute to implementing a highly integrated multilayer redistribution layer in the packaging substrate.

### Manufacturing Step

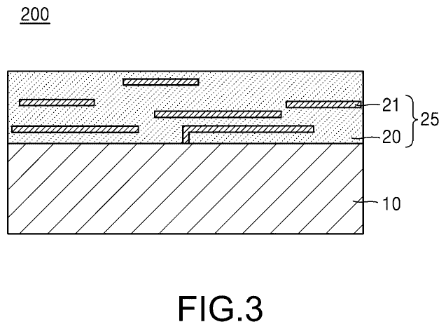

FIG. 3 is a conceptual diagram illustrating a packaging substrate manufactured according to the manufacturing method of the present disclosure. The manufacturing method of the packaging substrate of the present disclosure will be described with reference to FIG. 3.

In the manufacturing step, a packaging substrate (200) may be manufactured from a base substrate (100) in which a patterned insulating layer (20) is formed.

In the manufacturing step, the conductive layer (21) may be formed in a region where the insulating layer (20) is etched and removed through plasma etching, in particular, in a through-hole, to manufacture a redistribution layer.

The conductive layer (21) may be formed by a dry method or a wet method.

The dry method is a method in which a seed layer is formed by performing sputtering in a region where the conductive layer (21) is to be disposed, and plating is performed in the region where the seed layer is formed to form the conductive layer (21). During the formation of the seed layer, metals such as titanium, chromium, or nickel may be sputtered, and these metals and copper may be sputtered together. Through sputtering, an anchor effect may appear due to the interaction between the surface where the conductive layer (21) is to be disposed and the deposited metal particles, which may improve the adhesion of the conductive layer (21).

The wet method is a method in which a primer is applied to a portion where the conductive layer (21) is to be formed, and then metal plating is performed. The primer may include a compound having a functional group such as an amine. Depending on the intended level of adhesion, the primer may include both a compound having a functional group such as an amine and a silane coupling agent. When applying a silane coupling agent, the surface to be primed may be pretreated with the silane coupling agent, and then a compound having an amine group may be coated on the pretreated region to form a primer layer.

After forming the seed layer or the primer layer, a metal may be plated to form the conductive layer (21). Although copper plating may be applied when forming the conductive layer (21), it is not limited thereto. Before the metal plating, a region in the seed layer or the primer layer where the conductive layer (21) is not to be formed may be deactivated, or a region where the conductive layer (21) is to be formed may be activated before performing the plating. The activation or deactivation treatment method may include optical irradiation treatment such as irradiating light of a specific wavelength, or chemical treatment. However, without applying activation or deactivation treatment, metal plating may be performed and then the conductive layer (21) may be patterned by etching according to a predetermined shape.

When the patterned insulating layer (20) includes a hole pattern, the conductive layer (21) may be formed in the through-holes in the insulating layer (20). The conductive layer (21) may electrically connect a conductive layer (not shown) located on the upper side and a conductive layer (not shown) located on the lower side based on the conductive layer (21).

When the predesigned structure of the first redistribution layer (25) is a multilayer structure, another patterned insulating layer (20) and conductive layer (21) may be formed on the patterned insulating layer (20) and the conductive layer (21). The patterned insulating layer (20) and conductive layer (21) to be disposed thereon may be formed by the methods described above.

When the first redistribution layer (25) has a multilayer structure, a conductive layer (21) with a smaller width may be disposed toward the upper side in the first redistribution layer (25). A conductive layer (21) with a thinner thickness may be disposed toward the upper side in the first redistribution layer (25). A conductive layer (21) with a smaller pitch may be formed toward the upper side in the first redistribution layer (25). Through this, the first redistribution layer (25) may form a stable electrical connection with a semiconductor device having a fine pattern.

The manufacturing step may further include a process of forming a second redistribution layer (not shown) disposed under the core substrate (10), if necessary. The second redistribution layer may have a single-layer structure or a multilayer structure. The redistribution layer formed under the core substrate (10) may be formed by the same method as described above.

The second redistribution layer may have a single-layer structure or a multilayer structure.

When the second redistribution layer has a multilayer structure, a conductive layer with a wider width may be disposed toward the lower side in the second redistribution layer. A conductive layer with a thicker thickness may be disposed toward the lower side in the second redistribution layer. A conductive layer with a larger pitch may be formed toward the lower side in the second redistribution layer. Through this, the second redistribution layer may form a stable electrical connection with a main board in which a wide or thick conductive layer is formed.

In the manufacturing step, by completing the formation of the redistribution layer having a predesigned structure on the upper and/or lower side of the core substrate (10), the packaging substrate (200) may be prepared.

If necessary, in the manufacturing step, upper terminals and the like may be additionally formed on the upper and/or lower side of the packaging substrate (200), and bumps may be additionally formed on the lower side of the packaging substrate (200). The bumps may be disposed in a predetermined shape under the redistribution layer disposed under the core substrate (10). For example, the bumps may be disposed on a portion of the lower surface of the packaging substrate (200) to contact a main board or the like.

### Manufactured Packaging Substrate

The packaging substrate (200) manufactured according to the manufacturing method of the present disclosure may include the core substrate and the patterned insulating layer (20) disposed on the core substrate.

The packaging substrate (200) may further include a conductive layer (21) surrounded by the patterned insulating layer (20).

Since the description regarding the material and structure of the core substrate (10), the insulating layer (20), and the conductive layer (21) is redundant with the above, it is omitted.

The patterned insulating layer (20) may include through-holes formed in the thickness direction of the insulating layer (20). The conductive layer (21) may be formed in the through-holes.

The conductive layer (21) surrounded by the patterned insulating layer (20) may be formed on the patterned insulating layer (20) by the above-described dry method or wet method.

The insulating layer (20) may include the through-hole pattern. The diameter of the through-holes included in the insulating layer (20) may be 3 μm to 50 μm. The diameter may be 5 μm or more. The diameter may be 7 μm or more. The diameter may be 40 μm or less. The diameter may be 30 μm or less. The diameter may be 20 μm or less. The diameter may be 15 μm or less. In such a case, a through-hole pattern having a higher pattern density may be stably implemented in the insulating layer (20).

Hereinafter, the present disclosure will be described more specifically through concrete examples. The following examples are merely illustrative to assist in understanding the present disclosure and are not intended to limit the scope of the present disclosure.

### Manufacturing Example: Manufacturing of Packaging Substrate

Example 1: A base substrate was prepared by forming an insulating layer through vacuum lamination of a build-up film (Ajinomoto Build-up Film, ABF) manufactured by Ajinomoto Co. on the top surface of a glass plate SG7.8 produced by Corning Inc.

A metal film was formed on the insulating layer. Specifically, a first metal layer having a thickness of 50 μm was formed by a sputtering process using a titanium target on the upper surface of the insulating layer, and a second metal layer having a thickness of 100 μm was formed on the first metal layer by a sputtering process using a copper target.

A resist composition of the DRY FILM PHOTEC (RY series) from Resonac was coated and cured on the metal film to form a resist film having a thickness of 15 μm. The resist film was exposed to an electron beam, and the exposed resist film was developed to form a resist pattern film in which a plurality of hole patterns having a diameter of 7 to 10 μm were formed. Thereafter, the metal film was patterned using an etching solution to form a metal pattern film including a first metal pattern film formed from the first metal layer and a second metal pattern film formed from the second metal layer, thereby completing an etching mask with a thickness of 165 μm.

The base substrate having the etching mask formed thereon was placed in an etching chamber, and plasma etching was performed to form a hole pattern in the insulating layer. During plasma etching, the plasma power was applied to be 1.5 kW or more, and a first etching gas NF₃ at 150 sccm and a second etching gas O₂ at 150 sccm were supplied into the chamber.

After patterning the insulating layer, a cleaning process was performed on the base substrate. Specifically, the base substrate was immersed in a water bath, and ultrasonic cleaning was performed for 300 seconds by applying a vibration frequency of 20 kHz to 130 kHz.

After cleaning, it was confirmed that no resist pattern film remained on the metal pattern film. Thereafter, the metal pattern film was removed with an etching solution to complete the packaging substrate.

Example 2: A packaging substrate was manufactured under the same conditions as in Example 1, except that the thickness of the resist pattern film was applied to be 20 μm.

Comparative Example 1: A packaging substrate was manufactured under the same conditions as in Example 1, except that only a second metal pattern layer having a thickness of 150 μm was used as the metal pattern film, and the vibration frequency of the cleaning process was applied to be 100 kHz.

Comparative Example 2: The insulating layer was patterned under the same conditions as in Example 1, except that the thickness of the resist pattern film was applied to be 25 μm. After patterning, it was confirmed that the resist pattern film remained on the metal pattern film, and the remaining resist pattern film was stripped and removed. After removing the resist pattern film, the base substrate was immersed in a water bath, and ultrasonic cleaning was performed for 300 seconds by applying a vibration frequency of 100 kHz. After cleaning, the metal pattern film was removed with an etching solution to complete the packaging substrate.

Comparative Example 3: A packaging substrate was manufactured under the same conditions as in Example 1, except that the thickness of the resist pattern film was applied to be 10 μm, and the vibration frequency of the cleaning process was applied to be 100 KHz.

Comparative Example 4: A packaging substrate was manufactured under the same conditions as in Example 1, except that only a second metal pattern layer having a thickness of 100 μm was used as the metal pattern film, and the vibration frequency of the cleaning process was applied to be 100 kHz.

The thicknesses related to the metal pattern film and the resist pattern film for each of the Examples and Comparative Examples are shown in Table 1 below, and the presence or absence of residual resist pattern film after plasma etching for each of the Examples and Comparative Examples is shown in Table 2 below.

### Evaluation Example: Evaluation of Damage to the Patterned Insulating Layer

In the packaging substrates manufactured in each of the Examples and Comparative Examples, the patterned insulating layer was observed using an optical microscope to evaluate whether damage occurred. If no damage occurred, it was evaluated as “Pass”; if damage occurred, it was evaluated as “Fail”.

The evaluation results for each of the Examples and Comparative Examples are shown in Table 2 below.

TABLE 1

| | | | | Ratio of | | Ratio of | |
|---|---|---|---|---|---|---|---|
| | | | | Second | | Resist | |
| | Thickness | Thickness | | Metal Pattern | | Pattern | Thickness |
| | of First | of Second | Thickness | Film to | Thickness | Film to | of |
| | Metal | Metal | of Metal | First Metal | of Resist | Metal | Etching |
| | Pattern | Pattern | Pattern | Pattern | Pattern | Pattern | Mask |
| | Film (μm) | Film (μm) | Film (μm) | Film | Film (μm) | Film | Film (μm) |
| Example 1 | 50 | 100 | 150 | 2 | 15 | 0.10 | 165 |
| Example 2 | 50 | 100 | 150 | 2 | 20 | 0.13 | 170 |
| Comparative | 0 | 150 | 150 | — | 15 | 0.10 | 165 |
| Example 1 | | | | | | | |
| Comparative | 50 | 100 | 150 | 2 | 25 | 0.17 | 175 |
| Example 2 | | | | | | | |
| Comparative | 50 | 100 | 150 | 2 | 10 | 0.07 | 160 |
| Example 3 | | | | | | | |
| Comparative | 0 | 100 | 100 | — | 15 | 0.15 | 115 |
| Example 4 | | | | | | | |

TABLE 2

| | Residual Resist Pattern | Damage to Insulating |
|---|---|---|
| | Film | Layer |
| Example 1 | X | Pass |
| Example 2 | X | Pass |
| Comparative | X | Fail |
| Example 1 | | |
| Comparative | ◯ | Pass |
| Example 2 | | |
| Comparative | X | Fail |
| Example 3 | | |
| Comparative | X | Fail |
| Example 4 | | |

After the patterning of the insulating layer, in Examples and Comparative Examples 1, 3, and 4, no resist pattern film remained on the metal pattern film, whereas in Comparative Example 2, the resist pattern film remained.

In the evaluation of damage to the insulating layer, Examples and Comparative Example 2 were evaluated as “Pass,” whereas Comparative Examples 1, 3, and 4 were evaluated as “Fail.”

The preferred embodiments of the present invention have been described in detail above, but the scope of the rights of the present invention is not limited thereto, and various modifications and improvements using the basic concept of the present invention as defined in the following claims by those skilled in the art are also within the scope of rights of the present invention.

What is claimed is:

1. A method for manufacturing a packaging substrate, comprising:
a preparation step of preparing a base substrate comprising a core substrate and an insulating layer disposed on the core substrate;
an etching step of selectively etching the insulating layer using an etching mask; and
a manufacturing step of manufacturing the packaging substrate from the base substrate after completing the etching step,
wherein the etching mask is disposed on the insulating layer and comprises a metal pattern film and a resist pattern film disposed on the metal pattern film.

2. The method of claim 1,
wherein the metal pattern film comprises a first metal pattern layer and a second metal pattern layer disposed on the first metal pattern layer, and
the first metal pattern layer comprises any one selected from the group consisting of titanium, nickel, chromium, molybdenum, tungsten, aluminum, and combinations thereof.

3. The method of claim 2,
wherein the second metal pattern layer comprises copper.

4. The method of claim 2,
wherein the first metal pattern layer is disposed in contact with an upper surface of the insulating layer.

5. The method of claim 1,
wherein a thickness ratio of the resist pattern film to the metal pattern film is 0.15 or less.

6. The method of claim 2,
wherein a thickness ratio of the second metal pattern layer to the first metal pattern layer is 0.5 to 10.

7. The method of claim 1,
wherein a thickness of the metal pattern film is 100 μm to 250 μm.

8. The method of claim 1,
wherein the etching step comprises an etching mask formation process of forming the etching mask on the insulating layer and a plasma etching process of selectively plasma etching the insulating layer using the etching mask, and
the resist pattern film is removed during the plasma etching process.

9. The method of claim 8,
further comprising a cleaning process of ultrasonically cleaning the base substrate after completing the plasma etching process,
wherein a vibration frequency of the cleaning process is 20 kHz to 200 kHz.

10. The method of claim 1,
wherein the insulating layer after completing the etching step comprises through-holes having a diameter of 3 μm to 50 μm.
